(19) United States
(12) Patent Application Publication
(10) Pub. No.: US 2016/0081227 A1
(43) Pub. Date: Mar. 17, 2016

(54) VACUUM-ENHANCED HEAT SPREADER

(71) Applicant: The Regents of the University of Colorado, a body corporate, Denver, CO (US)

(72) Inventors: Yung-Cheng Lee, Boulder, CO (US); Shanshan Xu, Boulder, CO (US); Ronggui Yang, Boulder, CO (US); Collin Jennings Coolidge, Longmont, CO (US); Ryan John Lewis, Boulder, CO (US); Li-Anne Liew, Westminster, CO (US); Ching-Yi Lin, Longmont, CO (US)

(21) Appl. No.: 14/853,833

(22) Filed: Sep. 14, 2015

Related U.S. Application Data
(60) Provisional application No. 62/050,519, filed on Sep. 15, 2014.
(60) Provisional application No. 62/051,761, filed on Sep. 17, 2014.
(60) Provisional application No. 62/069,564, filed on Oct. 28, 2014.

(51) Int. Cl. H05K 7/20

(52) U.S. Cl. CPC H05K 7/20509

(57) ABSTRACT

Embodiments described in this disclosure include a heat spreader. The heat spreader may include a first layer having a thickness less than about 300 microns; a plurality of pillars disposed on the first layer and arrayed in a pattern, wherein each of the plurality of pillars have a height of less than 100 microns; a second layer having a thickness of less than 200 microns, wherein a portion of the first layer and a portion of the second layer are sealed together; and a vacuum chamber formed between the first layer and the second layer and within which the plurality of pillars are disposed.

### CROSS-REFERENCE TO RELATED APPLICATIONS

This application is a non-provisional of U.S. Provisional Patent Application No. 62/050,519, filed Sep. 15, 2014, titled VACUUM-ENHANCED HEAT SPREADER; a non-provisional of U.S. Provisional Patent Application No. 62/051,761, filed Sep. 17, 2014, titled MICROPILLAR-ENABLED THERMAL GROUND PLANE; and a non-provisional of U.S. Provisional Patent Application No. 62/069,564, filed Oct. 28, 2014, titled POLYMER-BASED MICROFABRICATED THERMAL GROUND PLANE, all three of which are incorporated by reference in their entireties.

### SUMMARY

Some embodiments described in this disclosure include a heat spreader. The heat spreader may include a first layer having a thickness less than about 300 microns; a plurality of pillars disposed on the first layer and arrayed in a pattern, wherein each of the plurality of pillars have a height of less than 50 microns; a second layer having a thickness of less than 200 microns, wherein a portion of the first layer and a portion of the second layer are sealed together; and a vacuum chamber formed between the first layer and the second layer and within which the plurality of pillars are disposed.

In some embodiments, the second layer may have a thermal conductivity that is less than the thermal conductivity of the first layer.

In some embodiments, the first layer may have a thermal conductivity greater than 200 W/mK, the second layer may have a thermal conductivity greater than 0.1 W/mK, and/or the plurality of pillars may have a thermal conductivity less than 0.2 W/m K.

In some embodiments, the first layer may include a thermal ground plane.

In some embodiments, the plurality of pillars may be arrayed in a pattern that varies in pillar density based on the location of the pillars.

In some embodiments, the second layer may be coupled with a housing of an electronic device or electronic system.

Some embodiments described in this disclosure include a heat spreader that includes a first layer; a second layer having a thickness less than the first layer and having a thermal conductivity less than the thermal conductivity of the first layer; and a vacuum chamber disposed between the first layer and the second layer, wherein the first layer and the second layer are hermitically sealed together forming the vacuum chamber.

In some embodiments, the first layer may have a thermal conductivity greater than 200 W/mK, the second layer may have a thermal conductivity greater than 0.1 W/mK, and/or the plurality of pillars may have a thermal conductivity less than 0.2 W/m K.

In some embodiments, the second layer may have a thickness of less than 200 microns.

In some embodiments, either or both the first layer and the second layer may include a material selected form the list consisting of copper-cladded Kapton, Kapton, copper, aluminum, ruthenium, graphite, metal, polymer, and polyimide, glass, ceramics, etc.

In some embodiments, the heat spreader may include a plurality of pillars coupled with the first layer and the second layer, and disposed within the vacuum chamber. In some embodiments, the plurality of pillars may have a height of less than 100 microns or 50 microns. In some embodiments, the plurality of pillars may have a thermal conductivity of between 0.05-0.2 W/m K. In some embodiments, each of the plurality of pillars may include a plurality of dissimilar layers. In some embodiments, each of the plurality of pillars may include a material selected from the list consisting of aerogel foam, polymer, glass, ceramics or other low thermal conductivity materials, etc. In some embodiments, each of the plurality of pillars is formed using a deposition process selected from the list consisting of atomic layer deposition, polymer deposition, polymer patterning, and molecular layer deposition. In some embodiments, the hear spreader may include at least a portion of a vacuum charging port or tube coupled with the vacuum chamber.

Some embodiments include a method that includes providing a first layer with a thickness of less than 300 microns; depositing a plurality of pillars on the first layer in a pattern, wherein each pillar of the plurality of pillars has a height of less than 200 microns; providing a second layer over the first layer and the plurality of pillars creating a vacuum chamber, wherein the second layer has a thickness of less than 200 microns; sealing a portion of the second layer with a portion of the first layer; and evacuating the vacuum chamber. In some embodiments, the pillars may be deposited on the first layer using a deposition method selected from the group consisting of atomic layer deposition, polymer deposition, polymer patterning, and molecular layer deposition.

### BRIEF DESCRIPTION OF THE FIGURES

These and other features, aspects, and advantages of the present disclosure are better understood when the following Detailed Description is read with reference to the accompanying drawings. The patent or application file contains at least one drawing executed in color. Copies of this patent or patent application publication with color drawing(s) will be provided by the Office upon request and payment of the necessary fee.

FIG. 1 is a graph illustrating the maximum allowable surface temperatures of a mobile system as a function of surface material and the contact time.

FIG. 2 is an example infrared image illustrating non-uniform heating (hot spot or region) in a mobile device without effective heat spreading according to some embodiments described herein.

FIG. 3 illustrates a polymer film before and after atomic layer deposition of Ru (ALD-Ru) coating according to some embodiments described herein.

FIG. 4A illustrates a vacuum-enhanced heat spreader according to some embodiments.

FIG. 4B illustrates a vacuum-enhanced heat spreader according to some embodiments.

FIG. 5A, FIG. 5B, FIG. 5C, and FIG. 5D illustrate examples of pillar size and arrangement of a vacuum-enhanced heat spreader/

FIG. 6A, FIG. 6B, and FIG. 6C illustrate three different heat spreaders with the same thickness of 250 microns served as the heat spreading layer that is attached to a 250 micron-thick polymer simulating the plastic cover of an electronic device or electronic system.

FIG. 7 illustrates the junction temperature plane and the skin temperature plane for the three heat spreaders shown in FIGS. 6A, 6B, and 6C.

FIG. 8A, FIG. 8B, and FIG. 8C are graphs of the skin temperature plane for the three heat spreaders shown in FIGS. 6A, 6B, and 6C.

FIG. 9A, FIG. 9B, and FIG. 9C are graphs of the simulated of the junction temperature plane for the three heat spreaders shown in FIGS. 6A, 6B, and 6C.

FIG. 10 illustrates three vacuum-enhanced heat spreaders with different pillar-to-pillar spacings and different layer thicknesses according to some embodiments.

FIG. 11 is a graph illustrating the temperature contours on the skin temperature plane of the three heat spreaders shown in FIG. 10.

FIG. 12 is a graph illustrating the temperature contours on the skin temperature plane of the three heat spreaders shown in FIG. 10.

FIG. 13 illustrates another embodiment of a vacuum-enhanced heat spreader with multiple vacuum-enabled insulation layers attached to a heat spreader according to some embodiments described herein.

FIG. 14 illustrates an example vacuum enhanced heat spreader with the vapor core with pillars serving as the vacuum layer in a thermal ground plane that includes a wicking structure.

### DETAILED DESCRIPTION

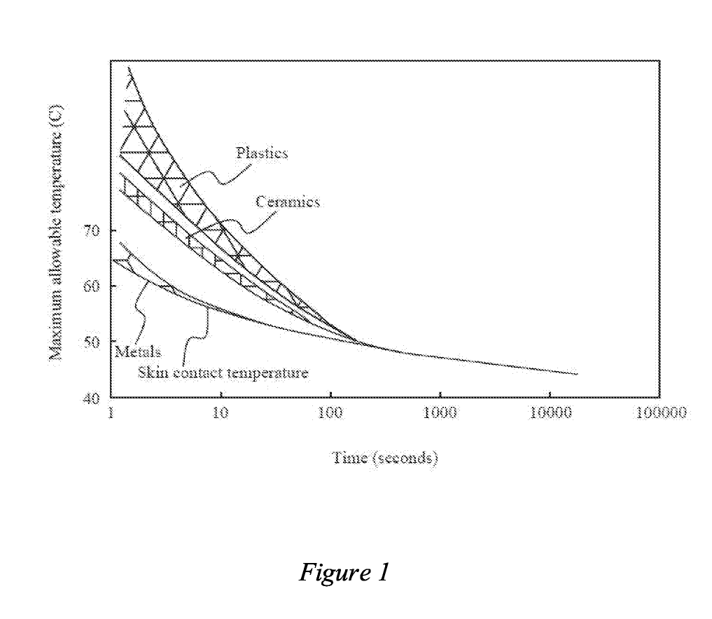

A challenge for mobile systems, e.g. smartphones, tablets and wearable electronics, is the control of the skin temperatures. The skin temperature is the temperature of an exterior portion of a device (e.g., the case) that is touched by fingers, hands, face, ears, or any other part of a human body. When the temperature of a portion of a device reaches beyond the maximum allowable temperature, a user would consider the temperature of the device to be hot. Of course, this “hot” perception is dependent on the surface materials and the duration of the contact; it also varies from one person to another one due to their difference in thermal physiology. FIG. 1 illustrates a graph of acceptable skin temperatures for a number of different materials with different touch time (contact duration).

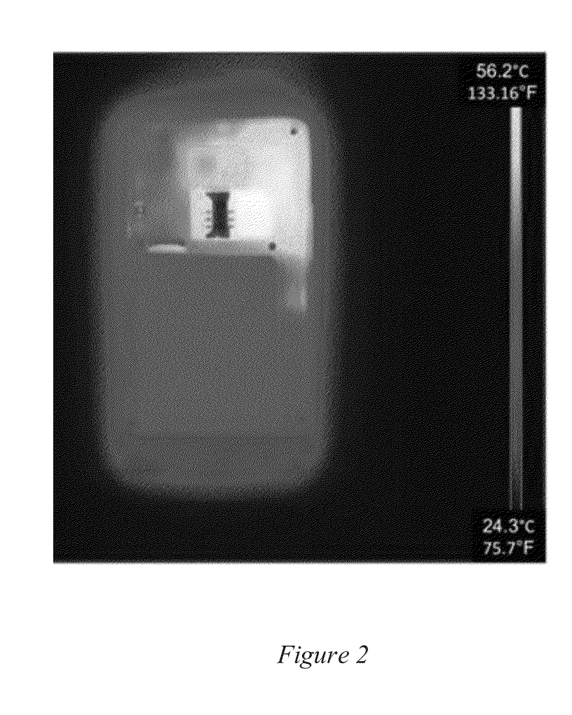

As illustrated in FIG. 2, a hot spot or region with a much higher temperature than the surroundings on a smart phone could be generated by an electronic chip such as, for example, a 5-Watt processor or a 1-Watt, small-size wireless amplifier. These hot spots or regions could be removed by effective heat spreading since the temperatures in the area outside these hot spots can be much lower.

Some embodiments of mobile systems may include a device having polymer layer coated with a thin metal layer and/or a method to coat polymers with a thin metal layer for cosmetic purposes. For example, Atomic Layer Deposition (ALD) can be used to deposit a thin film of ruthenium (Ru) on polyimide. The Ru can act as a cosmetic layer making the polyimide metallic shinning looking Polyimide is used in this example because of its low thermal conductivity and ability to survive the high temperatures experienced during the Ru deposition process.

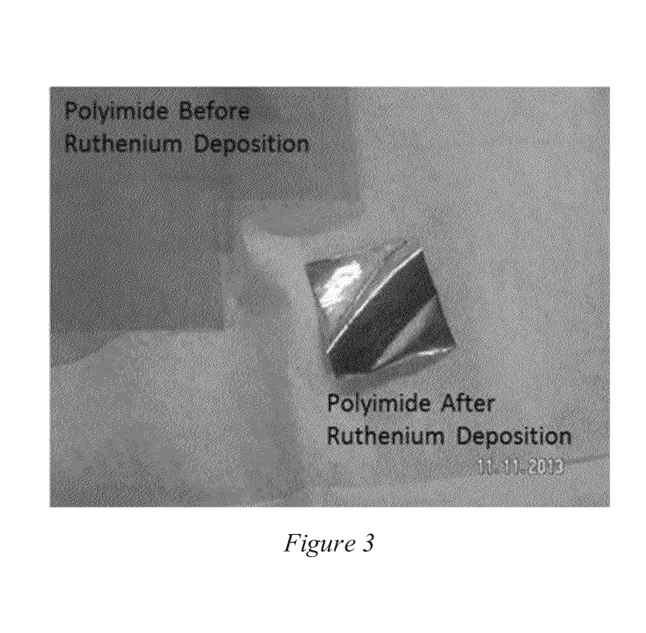

FIG. 3 illustrates a polyimide film before and after the Ru coating according to some embodiments described herein. The polyimide film may have any thickness such as, for example, a thickness of 0.05 mm, a 2 nm ALD Al₂O₃ seed layer to promote Ru nucleation, and/or a 100 nm Ru layer for a cosmetic surface coating. The specific thicknesses for the polyimide sheet, Al₂O₃ seed layer, and Ru cosmetic layer may have any thickness. However, it is very clear that optical appearance of the polyimide surface is changed substantially after Ru atomic layer deposition. Furthermore, the thermal conductivity of the film consisting of the polymer and the metal coating is very close to that of the polyimide since ALD is an extremely thin metal coating. As shown in FIG. 1, a low thermal conductivity casing is more tolerable for the same skin temperature. After Ru deposition, a thin layer of 3M Novec™ 1720 electronics grade coating may be applied. This coating may be used for displays and touch screens. Such an easy-clean, anti-smudge, 5 nm coating protects the Ru layer from scratches and corrosion. Other Novec coatings with different properties can be used also.

In some embodiments, an ALD metal coating over a polymer surface can provide one or more of the following benefits:
ALD metal layer can be extremely thin, e.g. 25 nm. As a result, its effect on the effective thermal conductivity of the polymer/metal layer is negligible.
ALD metal layer can be deposited at temperatures lower than 50° C. As a result, we are not limited to use high temperature polymer materials as the case material.
ALD metal layer covers very fine features even down to nano-scaled ones.
ALD metal layer combined with other ALD moisture barrier coatings can form excellent moisture/water barrier to protect the fine features on the surface and the devices enclosed by the polymer case.

As illustrated in FIG. 2, hot spots or regions are associated with heat dissipation from functional devices, such as microprocessors, amplifiers, memory units, etc. Such hot spots or regions can reach temperatures higher than the maximum allowable skin temperatures illustrated in FIG. 1. Thermal design can be implemented to ensure that the heat is well spread over the entire surface of the case without any hot spots or regions that reaches the maximum allowable temperature.

In some embodiments, a graphite heat spreader and/or a metallic heat spreader with high thermal conductivity, such as aluminum or copper, can be used as a heat spreader. A vacuum-enhanced heat spreader may also be used according to some embodiments described herein. A vacuum-enhanced heat spreader can include two layers separated by a vacuum chamber or air chamber. The vacuum chamber may include a plurality of pillars or channels that are coupled with the interior surfaces of each of the two layers. The two layers can include metallic or graphite layers. The vacuum-enhanced heat spreader has very anistropic effective thermal conductivity with a very high in-plane thermal conductivity that allow heat to spread on the surface and a very low cross-plane thermal conductivity due to the vacuum to avoid heat transfer from one side to the other before spreading.

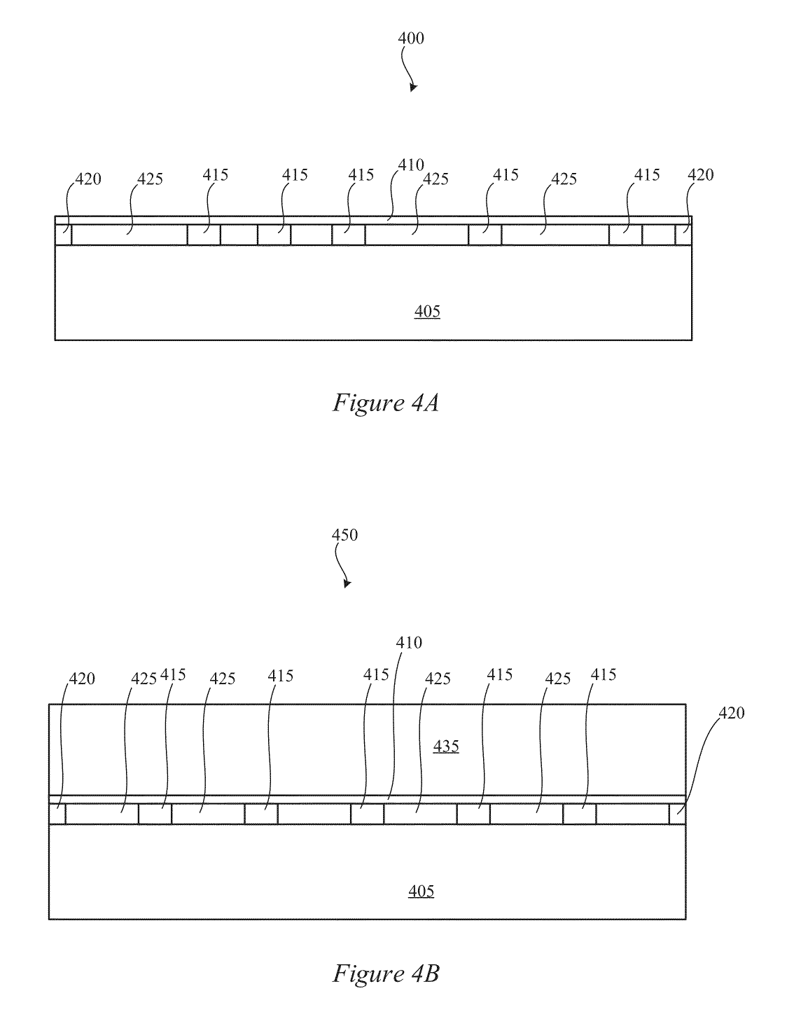

FIG. 4A illustrates an example vacuum-enhanced heat spreader 400 according to some embodiments described herein. The term “thermal ground plane-0” or “TGP-0” may be used, for example, to refer to a vacuum-enhanced heat spreader such as vacuum-enhanced heat spreader 400. In some embodiments, the vacuum-enhanced heat spreader 400 may include a first layer 405 and a second layer 410. A plurality of pillars 415 may be disposed between the first layer 405 and the second layer 410. A vacuum chamber 425 may be formed within the vacuum-enhanced heat spreader 400. In some embodiments, the first layer 405 and the second layer 410 may be sealed along one or more edges of the first layer 405 and the second layer 410.

In some embodiments, the first layer 405 may comprise any type of material that has a thermal conductivity greater than 200 W/mK. In some embodiments, the first layer may include a material that has a thermal conductivity greater than 50 W/mK, 100 W/mK, 200 W/mK, 500 W/mK, 1,000 W/mK. In some embodiments, the first layer 405 may include a copper, copper-cladded Kapton, polymeraluminum, glass, ceramics, a thermal ground plane, etc.

In some embodiments, the second layer 410 may comprise any type of material that has a thermal conductivity greater than 0.1 W/mK. In some embodiments, the second layer 410 may comprise any type of material that has a thermal conductivity greater than 0.2 W/mK, 0.5 W/mK, 1.0 W/mK, 1.5 W/mK, 2.0 W/mK, 5.0 W/mK, etc. In some embodiments, the first layer 405 may include a copper, copper-cladded Kapton, aluminum, polymer, glass, ceramics, a thermal ground plane, etc. The thermal ground plane, for example, may include a thermal ground plane described in U.S. Patent Application Publication No. 2011/0017431, which is incorporated into this disclosure for all purposes.

In some embodiments, the plurality of pillars 415 may be made from foam, polymer, copper, etc. In some embodiments, the plurality of pillars 415 may be fabricated using tens or hundreds of stacking layers of materials with nano-scaled thickness. Adjacent stacking layers, for example, may be made from dissimilar materials. In some embodiments, the plurality of pillars 415 may be deposited on the first layer using a deposition process such as atomic layer deposition, polymer deposition, polymer patterning, and molecular layer deposition. In some embodiments, the plurality of pillars 415 or the material from which the pillars are constructed may have a thermal conductivity either collectively or individually of less than 0.2 W/m K. In some embodiments, the plurality of pillars 415 or the material from which the between 0.05-0.2 W/m K.

In some embodiments, the plurality if pillars may have a cross-section that is rectangular, circular, or other shapes.

In some embodiments, the plurality of pillars 415 may be encapsulated. For example, the plurality of pillars may be encapsulated via electroplating or vapor or sputtering deposition. The encapsulated pillars may, for example, render negligible outgassing during the life time of the thermal insulation. In some embodiments, to reduce radiation heat transfer, the plurality of pillars 415 can be coated with low emissivity coatings, such as, for example, a very thin gold or silver layer.

In some embodiments, the first layer 405 and the second layer 410 may be sealed along one or more edges of the first layer 405 and one or more edges of the second layer 410. In some embodiments, the first layer 405 and the second layer 410 may be sealed using any type of sealing technology such as, for example, welding, laser welding, ultrasonic welding, thermo-compression, etc. In some embodiments, the first layer 405 and the second layer 410 may be sealed using various types of materials such as, for example, solder, glue, epoxy, etc.

In some embodiments, the vacuum chamber 425 may be evacuated to create a vacuum within the vacuum chamber 425. In some embodiments, a tube may be coupled with the heat spread 400 that can be coupled with a vacuum pump. Air and/or other gasses can be removed from the vacuum chamber 425 through the tube using the vacuum pump. In some embodiments, the vacuum level can be as low as 10⁻⁴ or 10⁻⁶ ton. Once a vacuum has been created the tube may be sealed, crimped or pinched. Various other techniques may be used to create a vacuum within the vacuum chamber 425. In some embodiments, the plurality of pillars 415 may create one or more channels within the vacuum chamber 425.

The vacuum-enhanced heat spreader 400 may include any number of additional layers and/or components. FIG. 4B is an example.

FIG. 4B illustrates an example vacuum-enhanced heat spreader 450 with a first layer 405, a second layer 410, a plurality of pillars 415 disposed between the first layer 405 and the second layer 410, and a third layer 435. The third layer, for example, may be plastic cover that is the plastic cover of an electronic device such as, for example, a mobile phone, tablet, computer, etc. Various other layers may be included.

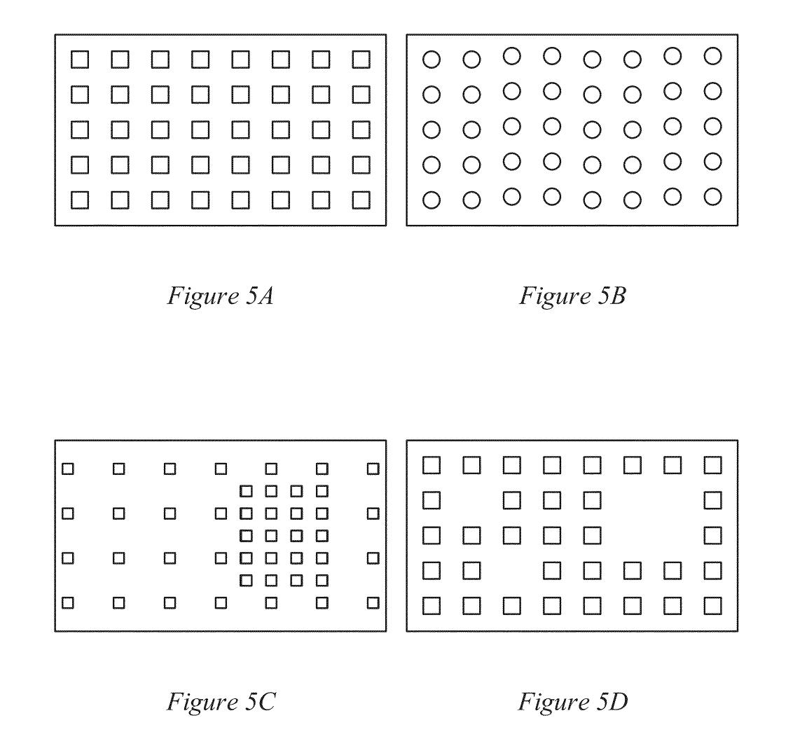

FIG. 5A, FIG. 5B, FIG. 5C, and FIG. 5D illustrates a top view of a plurality of pillars 415 arrayed on a first layer 405. The pillars shown in FIG. 5A have a rectangular (or square) cross-section. In some embodiments, pillars may have at least one dimension of less than about 10 mm, 5 mm, 2 mm, 1 mm, 0.5 mm, 0.25 mm, 0.1 mm, 0.05 mm, 0.2 mm, 0.1 mm, etc. The pillars shown in FIG. 5B have a circular cross-section. Various other cross-section shapes can be used. In some embodiments, pillars may have a radius or diameter of less than about 10 mm, 5 mm, 2 mm, 1 mm, 0.5 mm, 0.25 mm, 0.1 mm, 0.05 mm, etc.

In some embodiments, the pillars may be spaced in a consistent pattern as shown in FIG. 5A and FIG. 5B. In other embodiments, the pillars may be spaced in a non-consistent pattern. FIG. 5C shows an array of pillars with a heightened concentration of pillars in a specific region. FIG. 5D shows an array of pillars with a lessened concentration of pillars in a specific region. In some embodiments, heat producing components may be placed near regions with a lower pillar concentration. In some embodiments, a vacuum-enhanced heat spreader may have regions of low and high concentration of pillars.

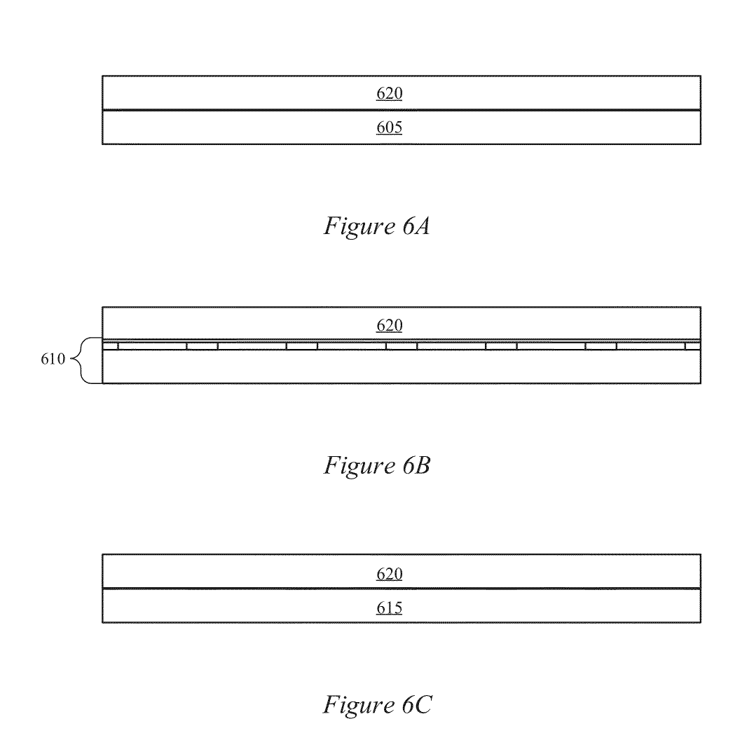

FIG. 6A illustrates a high thermal conductivity thermal ground plane (TGP) 605, FIG. 6B illustrates a vacuum-enhanced heat spreader (TGP-0) 610, and FIG. 6C illustrates a copper block 615 each with the same thickness (e.g., about 250 microns) coupled a polymer or plastic cover 620 of an electronic device and/or system. Testing these three devices an 8 mm×8 mm chip with 2.5 Watt heat dissipation was attached to the bottom of each heat spreading layer. The heat was transferred from the chip, spread by these three different heat spreading devices, and conducted to the plastic cover 620. The heat is then is removed by the air at 20° C. through a combined convection and radiation heat transfer coefficient of 20 W/m²K.

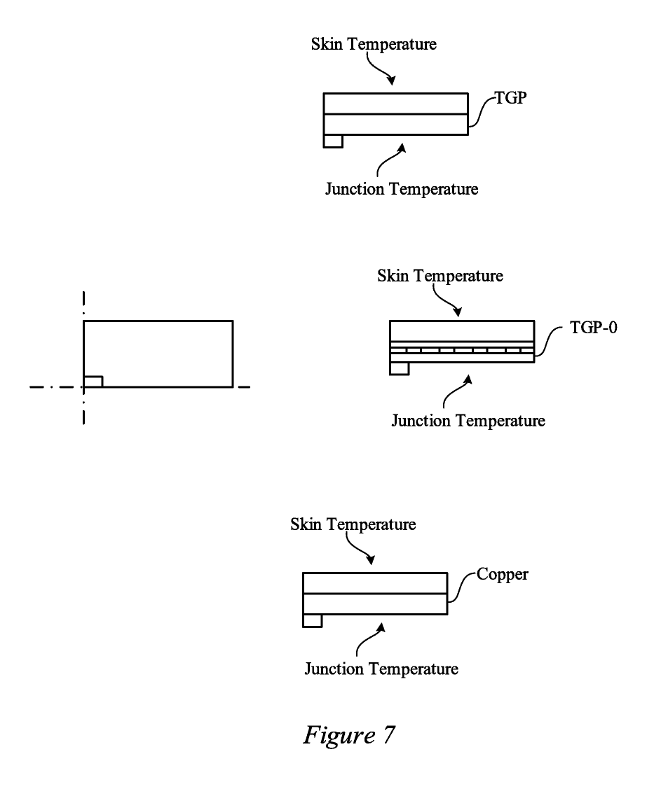

FIG. 7 illustrates the junction temperature plane and the skin temperature plane for the three heat spreaders shown in FIGS. 6A, 6B, and 6C. The junction temperature plane (bottom surface of the heat spreader in contact with the heat dissipating object) and the skin temperature plane (top surface of the plastic cover 620) are shown for each heat spreader.

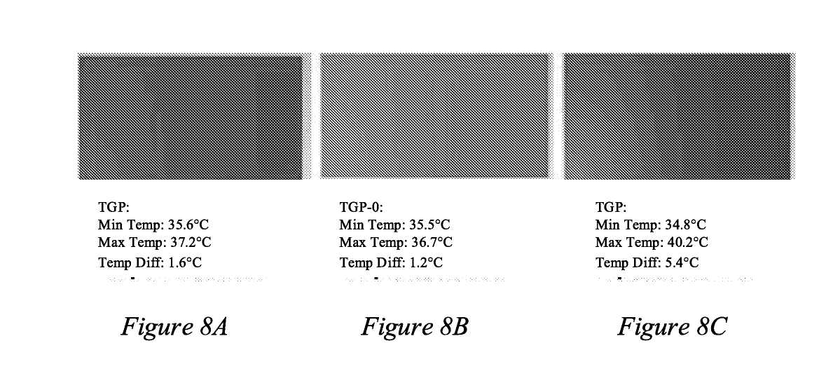

FIG. 8A, FIG. 8B, and FIG. 8C illustrates the temperature contours on the skin temperature plane of the three heat spreaders shown in FIGS. 6A, 6B, and 6C respectively when the attached chip generates heat. In this example of vacuum-enhanced heat spreader (TGP-0), a 150 um thick copper heat spreader with an area size of 10 cm×5 cm is bonded to a 70 um thick copper layer of the same size through any array of 30 um thick polymer pillars. The dimension of the polymer pillar is 200 um×200 um; the spacing between the pillars is 1 mm. In this example, with copper heat spreader 615 shown in FIG. 6C the maximum skin temperature on the skin temperature plane is 40.2° C., which is 5.4° C. higher than the minimum skin temperature of 34.8° C. With vacuum-enhanced heat spreader 610 shown in FIG. 6B, the maximum skin temperature on the skin temperature plane decreases to only 36.7° C. and the minimum skin temperature on the skin temperature plane is increased to 35.5° C. producing a much lower temperature differential across the heat spreader: the differential is reduced from 5.4° C. to only 1.2° C. The use of the vacuum-enhanced heat spreader shown in FIG. 6B reduces the thickness of the copper heat spreading layer to only 150 um, but it indeed forces much more effective heat spreading than a 250 um copper-only heat spreader.

Using thermal ground planes with assumed effective thermal conductivity of 1,500 W/mK, the skin temperature difference on the skin temperature plane is also reduced to only 1.6° C. The decrease of the temperature difference from 5.4 to 1.6 or 1.2° C. is significant. This temperature difference may be sensible for body (finger, ear) touch.

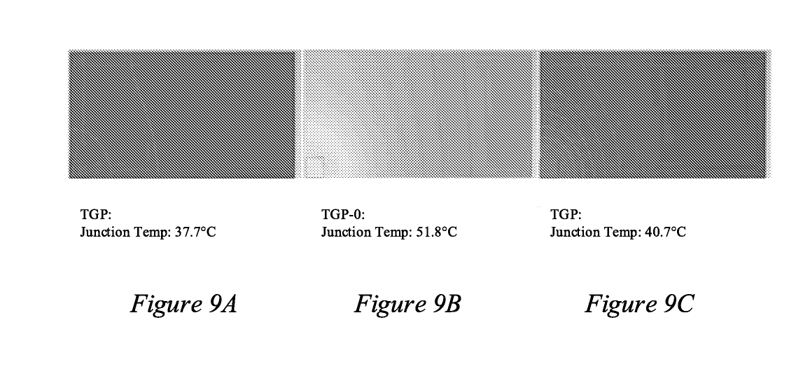

FIG. 9A, FIG. 9B, and FIG. 9C present the temperature contours on the junction temperature plane (the plane of the heat spreader in contact with the chip) in the three heat spreaders shown in FIGS. 6A, 6B, and 6C respectively. In this example, with the vacuum enhanced heat spreader 610, the junction temperature, may increase from 40.7 to 51.8° C. The junction temperature of the TGP with assumed effective thermal conductivity of 1,500 W/mK is 37.7° C., which is the lowest. With such a high thermal conductivity, the TGP can reduce both skin and junction temperatures.

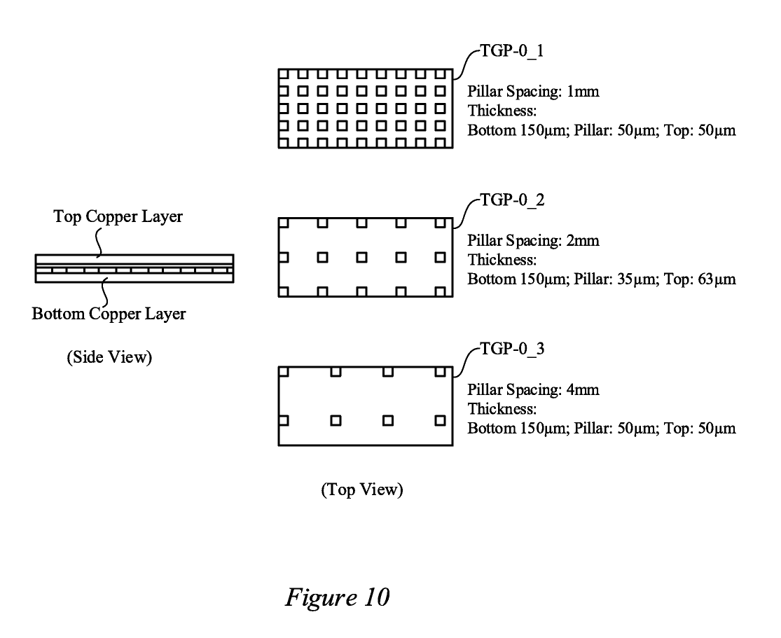

FIG. 10 illustrates three vacuum-enhanced heat spreaders with different pillar-to-pillar spacings and different layer thicknesses according to some embodiments. The three vacuum-enhanced heat spreaders have pillar-to-pillar spacings of 1 mm, 2 mm, and 4 mm, respectively and pillar heights of 50 um and 35 um. All three vacuum-enhanced heat spreaders have the same total thickness of 250 um.

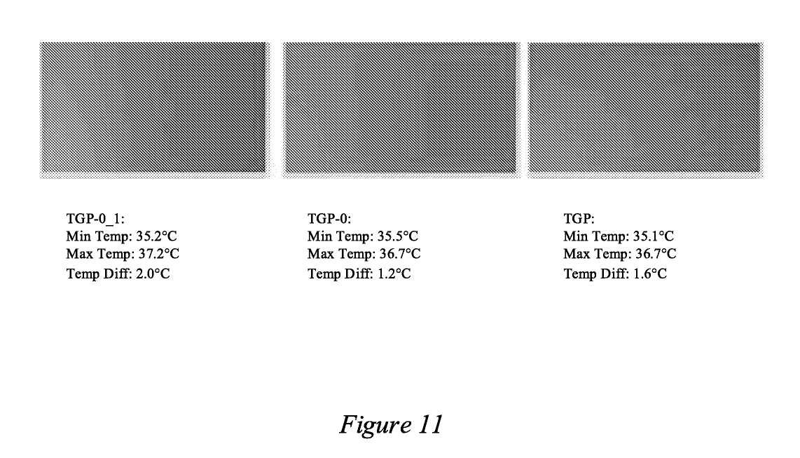

FIG. 11 illustrates the temperature contours on the skin temperature plane of the three heat spreaders shown in FIG. 10. The temperature difference can be increased from the above-mentioned 1.2° C. to 2.0° C. when the spacing is changed from 2 mm to 1 mm.

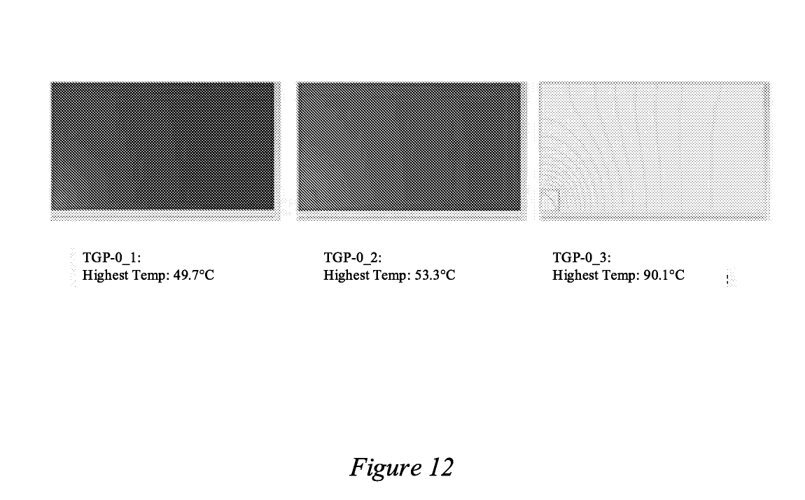

FIG. 12 illustrates the junction temperatures of the vacuum-enhanced heat spreaders shown in FIG. 10. The junction temperatures are reduced to 49.7° C. from 53.3° C. by changing the pillar-to-pillar spacing from 2 mm to 1 mm. If both the pillar spacing and the copper thickness of the top layer are changed, the temperature difference could increase from 1.2 to 1.6° C. while the junction temperature could also increase from 53.3 to 90.1° C.

The vacuum level within the heat spreader may also be adjusted to change the effectiveness of heat spreader to reach acceptable skin temperature and junction temperature.

In addition to thermal design, a mechanical design for the pillars is also needed. With vacuum, the top copper-cladded Kapton piece is pressed downward by the ambient atmospheric pressure. If pillar-to-pillar spacing is too large, this top piece could make a contact with the bottom heat spreader and the insulation performance would be degraded. A good design will consider pillar's materials, size, height, spacing to reach the minimum skin temperature while controlling the maximum allowable junction temperatures.

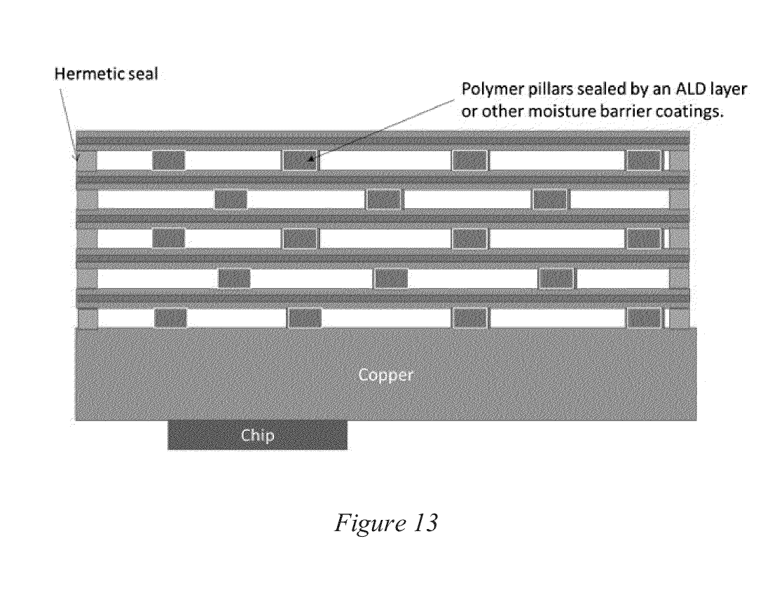

In some embodiments, multiple insulation layers (or multiple vacuum chambers can be placed between multiple layers) as shown in FIG. 13. The additional layers, for example, may provide additional parameters such as number of layers and staggering distance to fine tune thermal performance. Multiple layers may also, for example, provide redundancy in the event that one vacuum chamber leaks.

The various embodiments described herein can provide a number of benefits. In some embodiments, integration between a thermal insulation layer, a heat spreading layer and a case can be optimized by considering the final thermal and mechanical performance corresponding to different chip power levels and sizes with a goal to reduce the skin temperatures while keeping the maximum junction temperatures within the acceptable limit. The optimization may include designing the size, density, location, placement of pillars as well as the number of vacuum chambers (or vacuum layers) and/or the type of outer layers.

In some embodiments, depending on different chip power and size, embodiments can be modified to include a specific set of polymer pillars for each chip to reduce the maximum skin temperatures while maintaining acceptable maximum junction temperatures, structural deformations and number of defects of the moisture barrier coating.

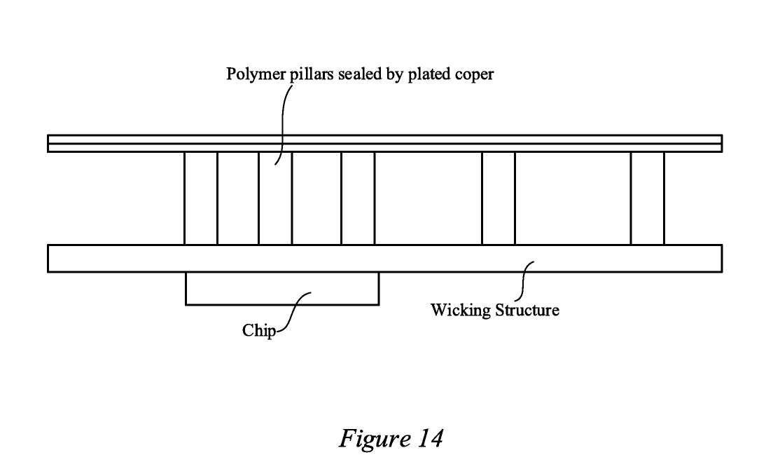

In some embodiments, atomic layer deposition or other moisture barrier coatings may be used to hermetic seal the vacuum cavity from outgassing. In some embodiments, a thermal ground plane may be reconfigured into a vacuum-enhanced heat spreader by arranging the pillars in the vapor core in a manner shown in FIG. 14. In normal operation, the vapor core is operating in a vacuum environment. The liquid moves along the wicking layer.

In some embodiments, atomic layer deposition and/or molecular deposition processes can be used to fabricate extremely low thermal conductivity pillars with alternative material layers.

In some embodiments, multiple hermetic sealed layers can be assembled to tolerate leakage and enhance reliability.

In some embodiments, the vacuum levels of vacuum chambers can be adjusted to meet different trade-off requirements between the skin temperatures, the junction temperatures, the battery temperatures and other temperatures.

In some embodiments, a copper heat spreader can be replaced by high thermal conductance graphite, thermal ground planes or other heat conductors.

In some embodiments, the use of polymer pillars or other low thermal conductivity pillars can be applied to fabricate spacers for the vapor core of a thermal ground plane in order to reduce heat conduction from a chip to the backside of the thermal ground plane.

Numerous specific details are set forth herein to provide a thorough understanding of the claimed subject matter. However, those skilled in the art will understand that the claimed subject matter may be practiced without these specific details. In other instances, methods, apparatuses, or systems that would be known by one of ordinary skill have not been described in detail so as not to obscure claimed subject matter.

The use of “adapted to” or “configured to” herein is meant as open and inclusive language that does not foreclose devices adapted to or configured to perform additional tasks or steps. Additionally, the use of “based on” is meant to be open and inclusive, in that a process, step, calculation, or other action “based on” one or more recited conditions or values may, in practice, be based on additional conditions or values beyond those recited. Headings, lists, and numbering included herein are for ease of explanation only and are not meant to be limiting.

While the present subject matter has been described in detail with respect to specific embodiments thereof, it will be appreciated that those skilled in the art, upon attaining an understanding of the foregoing, may readily produce alterations to, variations of, and equivalents to such embodiments. Accordingly, it should be understood that the present disclosure has been presented for-purposes of example rather than limitation, and does not preclude inclusion of such modifications, variations, and/or additions to the present subject matter as would be readily apparent to one of ordinary skill in the art.

That which is claimed:

1. A heat spreader comprising:
a first layer having a thickness less than about 300 microns;
a plurality of pillars disposed on the first layer and arrayed in a pattern, wherein each of the plurality of pillars have a height of less than 10 microns;
a second layer having a thickness of less than 200 microns, wherein a portion of the first layer and a portion of the second layer are sealed together; and
a vacuum chamber formed between the first layer and the second layer and within which the plurality of pillars are disposed.

2. The heat spreader according to claim 1, wherein the second layer has a thermal conductivity that is less than the thermal conductivity of the first layer.

3. The heat spreader according to claim 1, wherein:
the first layer has a thermal conductivity greater than 200 W/mK
the second layer has a thermal conductivity greater than 0.1 W/mK
the plurality of pillars have a thermal conductivity less than 0.2 W/m K.

4. The heat spreader according to claim 1, wherein the first layer comprises a thermal ground plane.

5. The heat spreader according to claim 1, wherein the plurality of pillars is arrayed in a pattern that varies in pillar density across the first layer.

6. The heat spreader according to claim 1, wherein the second layer is coupled with a housing of an electronic device.

7. A heat spreader comprising:
a first layer;
a second layer having a thickness less than the first layer and having a thermal conductivity less than the thermal conductivity of the first layer; and
a vacuum chamber disposed between the first layer and the second layer, wherein the first layer and the second layer are hermitically sealed together forming the vacuum chamber.

8. The heat spreader according to claim 7, wherein:
the first layer has a thermal conductivity greater than 200 W/mK
the second layer has a thermal conductivity greater than 0.1 W/mK
the plurality of pillars have a thermal conductivity less than 0.2 W/m K.

9. The heat spreader according to claim 7, wherein the second layer has a thickness of less than 200 microns.

10. The heat spreader according to claim 7, wherein either or both the first layer and the second layer comprise a material selected form the list consisting of copper-cladded Kapton, Kapton, copper, aluminum, ruthenium, graphite, metal, polymer, and polyimide.

11. The heat spreader according to claim 7, further comprising a plurality of pillars coupled with the first layer and the second layer, and disposed within the vacuum chamber.

12. The heat spreader according to claim 11, wherein the plurality of pillars has a height of less than 100 microns.

13. The heat spreader according to claim 11, wherein the plurality of pillars has a thermal conductivity of between 0.05-0.2 W/m K.

14. The heat spreader according to claim 11, wherein each of the plurality of pillars comprises a plurality of dissimilar layers.

15. The heat spreader according to claim 11, wherein each of the plurality of pillars comprise a material selected from the list consisting of aerogel foam, polymer, glass, ceramics, and other low thermal conductivity materials.

16. The heat spreader according to claim 11, further comprising a hermetic seal coating on the plurality of pillars, the hermetic seal coating comprising a material selected from the list consisting of a thin metal, thin ceramics, and atomic layer deposition layers.

17. The heat spreader according to claim 11, wherein each of the plurality of pillars is formed using a deposition process selected from the list consisting of atomic layer deposition, polymer deposition, polymer patterning, and molecular layer deposition.

18. A method comprising:
providing a first layer with a thickness of less than 300 microns;
depositing a plurality of pillars on the first layer in a pattern, wherein each pillar of the plurality of pillars has a height of less than 200 microns;
providing a second layer over the first layer and the plurality of pillars creating a vacuum chamber, wherein the second layer has a thickness of less than 200 microns;
sealing a portion of the second layer with a portion of the first layer; and
evacuating the vacuum chamber.

19. The method according to claim 18, wherein the pillars are deposited on the first layer using a deposition method selected from the group consisting of atomic layer deposition, polymer deposition, polymer patterning, glass deposition, glass patterning, ceramics deposition, ceramics patterning, atomic layer deposition and molecular layer deposition.

20. The plurality of pillars according to claim 18, further comprising a hermetic seal coating such as thin metal, thin ceramics, and atomic layer deposition layers to eliminate outgassing from the pillars.
